(19) United States
(12) Patent Application Publication
(10) Pub. No.: US 2009/0050980 A1
(43) Pub. Date: Feb. 26, 2009

(54) METHOD OF FORMING A SEMICONDUCTOR DEVICE WITH SOURCE/DRAIN NITROGEN IMPLANT, AND RELATED DEVICE

(75) Inventors: Shashank S. EKBOTE, Allen, TX (US); Srinivasan CHAKRAVARTHI, Murphy, TX (US); Ramesh VENUGOPAL, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/842,242

(22) Filed: Aug. 21, 2007

(51) Int. Cl. H01L 29/94; H01L 21/425

(52) U.S. Cl. 257/408; 438/527; 257/E21.473; 257/E29.345

(57) ABSTRACT

A method of forming a semiconductor device with source/drain nitrogen implant, and related device. At least some of the illustrative embodiments are methods comprising forming a gate stack over a substrate, implanting a dopant species into an active region adjacent to the gate stack, and reducing a diffusivity of the dopant species by implanting nitrogen into the active region.

### BACKGROUND

In today's electronics industry, devices are continually getting smaller, faster, and using less power, while simultaneously being able to support and perform a greater number of increasingly complex and sophisticated functions. One reason for these trends is an ever increasing demand for small, portable and multifunctional electronic devices. For example, cellular phones, personal computing devices, and personal audio devices (e.g., MP3 players) are in great demand in the consumer market. Such electronic devices rely on a limited power source (e.g., batteries) while providing ever-increasing processing capabilities and storage capacity.

Accordingly, there is a continuing trend in the semiconductor industry to manufacture low-cost, high-performance, and low-power integrated circuits (ICs). These goals have been achieved in great part by scaling down the dimensions of semiconductor ICs and thus increasing device and circuit densities. Achieving higher densities calls for smaller feature sizes, smaller separations between features and layers, and more precise feature shapes. The scaling down of IC dimensions can facilitate faster circuit performance (e.g., faster switching speeds) and can lead to higher effective yield in IC fabrication processes by providing (i.e., “packing”) more circuits on a semiconductor die and/or more die on a semiconductor wafer. However, as scaling moves into the nanometer-scale regime, scaling the physical dimensions alone is not sufficient as new phenomenon appear that, for example, reduce the transistor drive current.

### SUMMARY

The problems noted above are solved in large part by a method of forming a semiconductor device with source/drain nitrogen implant, and related device. At least some of the illustrative embodiments are methods comprising forming a gate stack over a substrate, implanting a dopant species into an active region adjacent to the gate stack, and reducing a diffusivity of the dopant species by implanting nitrogen into the active region.

Other illustrative embodiments are semiconductor devices comprising a substrate having a surface, an active region within the substrate comprising a dopant species implanted such that a peak concentration of the dopant species is located at a depth ‘x’ from the surface, and a nitrogen region comprising nitrogen implanted such that a peak concentration of the nitrogen is located at a depth ‘y’ from the surface. The depth ‘y’ is greater than the depth ‘x’.

Yet other illustrative embodiments are methods comprising forming a gate stack over a substrate, implanting boron into an active region adjacent to the gate stack, and reducing a diffusivity of the boron by implanting nitrogen into the active region.

### BRIEF DESCRIPTION OF THE DRAWINGS

For a more detailed description of the various embodiments, reference will now be made to the accompanying drawings, wherein:

FIG. 1 shows a perspective view of a MOS transistor;

FIG. 2 shows a cross sectional view illustrating the formation of a MOS transistor after formation of a polysilicon layer;

FIG. 3 shows a cross sectional view illustrating the formation of a MOS transistor after formation of a gate stack and source/drain extension regions; and

FIG. 4 shows a cross sectional view illustrating the formation of a MOS transistor after formation of source and drain regions.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct connection. Thus, if a first device couples to a second device, that connection may be through a direct connection, or through an indirect connection via other devices and connections.

The term “active region” means a region wherein a semiconductor device is formed within and/or on a semiconductor substrate, and wherein the active region does not comprise isolation structures, such as shallow trench isolation (STI) structures or field oxide (FOX) regions.

Unless otherwise stated, when a layer is said to be “deposited over the substrate” or “formed over the substrate”, it means that the layer is deposited or formed over any topography that already exists on the substrate.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment. Also, layers and/or elements depicted herein are illustrated with particular dimensions and/or orientations relative to one another for purposes of simplicity and ease of understanding, and actual dimensions and/or orientations of the layers and/or elements may differ substantially from that illustrated herein.

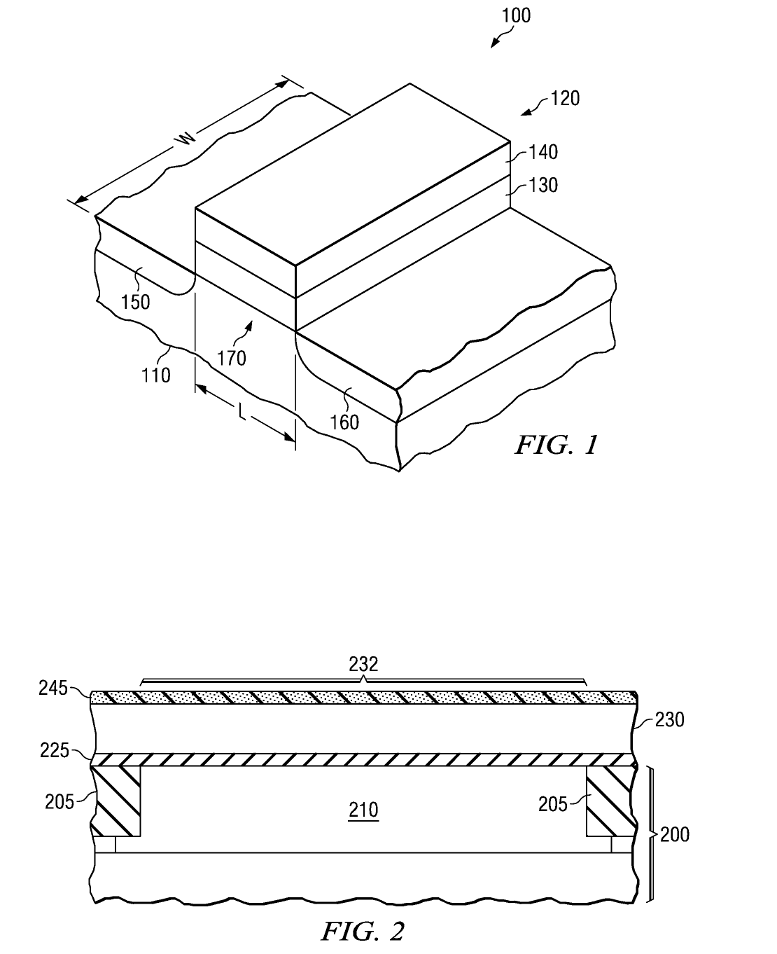

A fundamental building block of semiconductor ICs is the metal-oxide semiconductor (MOS) transistor. FIG. 1 illustrates a cross-section of a basic MOS transistor 100. The transistor 100 is fabricated on a semiconductor substrate 110 and comprises a gate stack 120. The gate stack 120 comprises a gate dielectric 130 (e.g., silicon dioxide) and a gate electrode 140 (e.g., polysilicon) on the gate dielectric 130. The transistor 100 also comprises a source region 150 and a drain region 160 each formed within the semiconductor substrate 110. A channel 170 is defined between the source and drain regions 150, 160, under the gate dielectric 130, and within the semiconductor substrate 1 10. The channel 170 has an associated channel length “L” and an associated channel width “W”. When a bias voltage greater than a threshold voltage (Vt) (i.e., turn-on voltage) for the transistor 100 is applied to the gate electrode 140 along with a concurrently applied bias voltage between the source and drain regions 150, 160, an electric current (e.g., a transistor drive current) flows between the source and drain regions 150, 160 through the channel 170. The amount of drive current developed for a given bias voltage (e.g., applied to the gate electrode 140 or between the source and drain regions 150, 160) is a function of, among others, the width-to-length ratio (W/L) of the channel 170. To enhance performance of the transistor 100 (e.g., increase drive current), physical dimensions and applied voltages are scaled down. As a result, MOS transistors have become cheaper, faster, and less power-hungry with each new technology generation. To date, most scaling of the transistor 100 physical dimensions has been achieved by thinning the gate dielectric 130 or reducing the channel length “L”.

The subject matter disclosed herein is directed to methods associated with construction of a semiconductor device, such as a MOS transistor. A semiconductor is a material (e.g., silicon or germanium) having properties somewhere between a conductor and an insulator. By adding impurities (e.g., by a process known as “doping”), a semiconductor can be classified as being electron-rich (N-type) or electron-poor (P-type). Through a series of semiconductor processing techniques (e.g., deposition, photolithography, etching, ion implantation), semiconductor materials are used to make semiconductor devices (e.g., transistors) which are in turn used to make integrated circuits (ICs). Moreover, N-type MOS transistors (NMOS) and P-type MOS (PMOS) transistors are often used together to form complementary metal-oxide semiconductor (CMOS) ICs.

As CMOS ICs are scaled down to the nanometer-scale regime, new challenges to enhancing transistor performance are encountered (e.g., polysilicon gate electrode depletion effects (“poly-depletion”)). Referring to FIG. 1, the poly-depletion effect is characterized by a polysilicon gate electrode 140 that is no longer fully conductive and contributes an additional capacitance (within the gate electrode 140) that is in series with a capacitance of the gate dielectric 130. This additional capacitance within the gate electrode 140 reduces the equivalent capacitance between the gate electrode 140 and the silicon substrate 110, which increases the effective thickness of the gate dielectric 130 (i.e., Tox Inversion), and results in reduced transistor 100 drive current. To overcome the poly-depletion effect, it is desirable to increase the doping concentration within the gate electrode 140. In some embodiments, the polysilicon gate electrode 140 and the source and drain regions 150, 160 are doped with a dopant species (e.g., boron for PMOS transistors, and phosphorous and/or arsenic for NMOS transistors) using, for example, a self-aligned ion implantation process (discussed below). By increasing a dose of the dopant species used for the ion implantation process (i.e., an implant dose), it is possible to increase the doping of the polysilicon gate electrode 140 to a point at which the poly-depletion effect is removed or at least lessened. However, diffusion of the dopant species through the source and drain regions 150, 160 can adversely affect performance of the transistor 100. By implanting nitrogen together with the dopant species implanted during the ion implantantion, it is possible to reduce the diffusivity of the dopant species such that the dopant species does not diffuse through the source and drain regions 150, 160 enough to be detrimental to performance of the transistor 100.

For purposes of this disclosure, the nitrogen implant may be equivalently referred to as a nitrogen co-implant. However, use of the term “co-implant” does not limit how or when the nitrogen implant may be performed. In some embodiments, a nitrogen implant is simultaneous with a dopant species implant. In other embodiments, the nitrogen implant is sequentially before the dopant species implant. In yet other embodiments, the nitrogen implant is sequentially after the dopant species implant.

Diffusion of a dopant species beyond the desired source and drain regions 150, 160 may also be observed in cases where the dose of the dopant species used for the ion implantation process remains substantially constant but where the physical dimensions of the transistor 100 (e.g., a sidewall spacer dimension) are scaled down from one technology generation to the next. In such a case (i.e., where the dose of the dopant species for a given technology generation is substantially the same as a dose used for a previous technology generation), a nitrogen co-implant can also be used to reduce the diffusivity of the dopant species. Thus, embodiments disclosed herein relate to performing a nitrogen co-implant together with an ion implantation process to reduce the diffusivity of a dopant species within the source and drain regions 150, 160.

Referring to FIG. 2, isolation structures 205 are formed within a substrate 200 in order to define an active area 232 and to electrically isolate neighboring devices (e.g., transistors) from one another. In some embodiments, the substrate 200 comprises a P-type single crystal silicon substrate that may be formed, for example, by epitaxial growth. In other embodiments, the substrate 200 comprises a silicon germanium (SiGe) substrate or a silicon-on-insulator (SOI) substrate. The isolation structures 205 can be formed by a shallow trench isolation (STI) process. A well 210 is then formed within the substrate 200, for example, by performing an ion implantation into the substrate 200 followed by a high-temperature anneal. The well 210 is doped with N-type dopants (e.g., phosphorous or arsenic) or P-type dopants (e.g., boron) depending on the type of transistor (NMOS or PMOS) to be formed within the well 210.

A dielectric layer 225 is then formed over the substrate 200. The dielectric layer 225 comprises a non-conductive material (e.g., a silicon oxide (i.e., SiO₂), a silicon oxynitride, or a high dielectric constant (“high-K”) material such as a hafnium-based metal-oxide or a hafnium-based silicate). Depending on the material used for the dielectric layer 225, the dielectric layer 225 can be formed by a variety of techniques (e.g., thermal oxidation, thermal oxidation followed by a thermal nitridation, atomic layer deposition (ALD), or chemical vapor deposition (CVD)).

A polysilicon layer 230 (i.e., a gate electrode) is then formed over the dielectric layer 225. The polysilicon layer 230 is formed, for example, by using a low-pressure chemical vapor deposition (LPCVD) process. An antireflective coating (ARC) layer 245 (e.g., an organic or inorganic ARC layer) can be formed over the polysilicon layer 230 for patterning of a gate stack as discussed below. ARC layers are used to suppress reflections from underlying layers during a lithographic process and to improve the quality of a subsequently patterned layer. The ARC layer 245 can be removed after the gate stack has been patterned and etched.

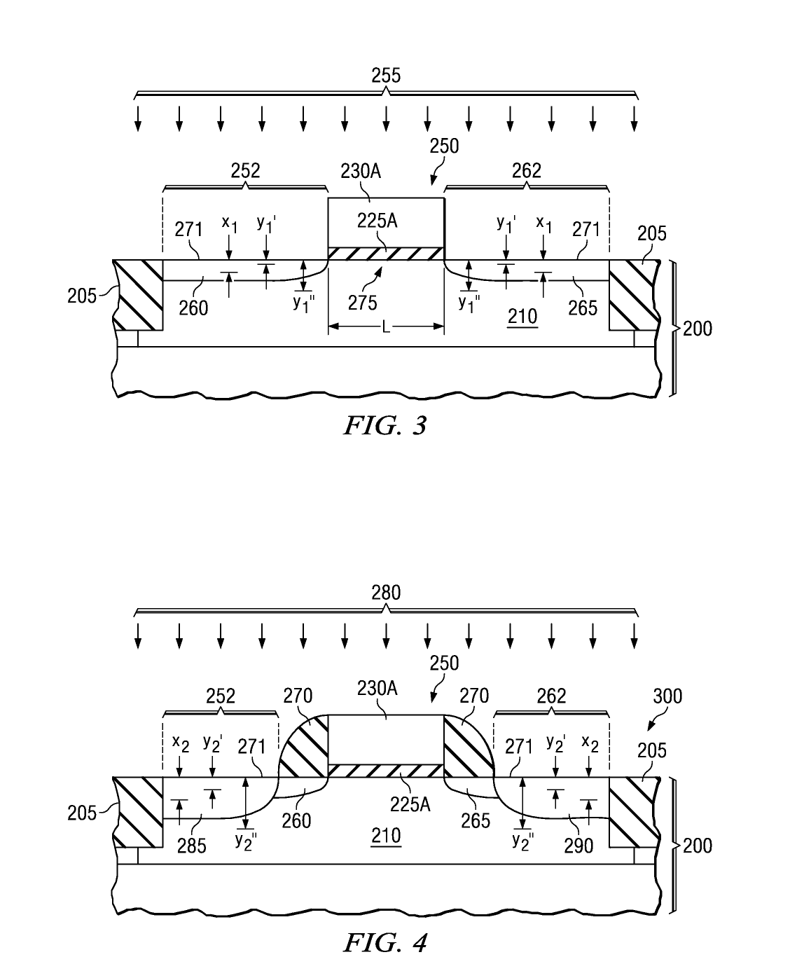

As shown in FIG. 3, the ARC layer 245 (FIG. 2) has been removed (e.g., by a wet or dry etching process), and the dielectric layer 225 and the polysilicon layer 230 (FIG. 2) have been patterned and etched to form a gate stack 250, where the gate stack 250 comprises a dielectric layer 225A and a polysilicon layer 230A. The patterning process can be performed in any suitable manner, such as with lithographic techniques where lithography broadly refers to processes for transferring one or more patterns between various media. In photolithography, a light sensitive layer (e.g., photoresist) is deposited (e.g., by spin-coating) upon a layer to which a pattern is to be transferred. The light sensitive layer is then patterned by exposing it to one or more types of radiation or light which selectively pass through an intervening mask which comprises a pattern defined by various transparent and opaque regions. The light causes exposed or unexposed regions of the light sensitive layer to become more or less soluble, depending on the type of light sensitive layer used. A developer (i.e., an etchant) is then used to remove the more soluble areas, thereby transferring the mask pattern to the light sensitive layer. The patterned light sensitive layer can then serve as a mask for an underlying layer or layers, wherein the underlying layer or layers can be etched to form the pattern as defined by the light sensitive layer. In particular, the dielectric layer 225 and the polysilicon layer 230 (FIG. 2) are patterned simultaneously by way of the light sensitive layer, and various (dry or wet) etchants can be used to remove each of the layers in sequence, using the patterned light sensitive layer as a mask. After etching of the dielectric layer 225 and the polysilicon layer 230 (FIG. 2) to form the gate stack 250, the light sensitive layer is stripped by an “ashing” process, where for example, the light sensitive layer is removed by exposure to oxygen ambient at a high-temperature in the presence of radio frequency (RF) power.

After forming the gate stack 250 and stripping the light sensitive layer, an ion implantation 255 is performed. Depending on the type of transistor being formed (NMOS or PMOS), the ion implantation 255 implants either N-type or P-type dopants (e.g., boron for PMOS transistors, and phosphorous and/or arsenic for NMOS transistors). In some embodiments, the ion implantation 255 comprises a nitrogen co-implant, where the nitrogen implant energy (i.e., projected range (Rp) of the implant) and dose (Q) (i.e., concentration of the N-type or P-type dopant) are set according to the projected range and dose of the N-type or P-type dopants. In some embodiments, the projected range of the nitrogen co-implant is between about 0.33 and about 1.33 of the projected range of the N-type or P-type dopant implant. Thus, in some embodiments a peak concentration of the N-type or P-type dopant is located at a depth xi from a surface 271 of the substrate 200, and a peak concentration of the nitrogen is located between a depth y₁′ (corresponding to about 0.33 of the depth x₁) and a depth y₁″ (corresponding to about 1.33 of the depth x₁) from the surface 271. Each of x₁, y₁′, and y₁″, as illustrated in FIG. 3 and herein described, are intended to indicate a depth from the surface 271 and are not intended to indicate any lateral positioning of either the dopant or the nitrogen. Also, in some embodiments, the dose of the nitrogen co-implant is between about 0.7 and about 1.3 of the N-type or P-type dopant dose. The ion implantation 255 is performed into an active region 252 and into an active region 262 in order to define a lightly doped source region 260 and a lightly doped drain region 265. The ion implantation 255 is a self-aligned ion implantation process in that the gate stack 250 is used as a mask to define each of the lightly doped source and drain regions 260, 265. Thus, the gate stack 250 is simultaneously subjected to the ion implantation 255, and the ion implantation 255 also dopes the polysilicon layer 230A. However, the gate stack 250 masks a portion of the substrate 200 from the ion implantation 255, such that the lightly doped source and drain regions 260, 265 are formed within the substrate 200 immediately adjacent to the gate stack 250. The lightly doped source and drain regions 260, 265 may be equivalently referred to as source and drain extension regions. In some embodiments, a thermal process, such as a rapid thermal anneal, is performed to activate the dopants within the lightly doped source and drain regions 260, 265, which may cause a slight lateral diffusion of the lightly doped source and drain regions 260, 265 under the gate stack 250.

In some embodiments, a thin conformal oxide or nitride layer may be deposited over the gate stack 250 prior to the ion implantation 255 in order to protect (i.e., block the ion implantation 255) sidewalls of the gate stack 250. In some embodiments, the thin conformal oxide or nitride layer is used to block the ion implantation 255 from the polysilicon layer 230A. In this manner, the doping of the lightly doped source and drain regions 260, 265 can remain separate and independent of the doping of the polysilicon layer 230A.

Still referring to FIG. 3, a channel 275 is defined between the lightly doped source region 260 and the lightly doped drain region 265, under the gate dielectric 225A, and within the substrate 200. The channel 275 has an associated channel length “L” and an associated channel width. The lightly doped source and drain regions 260, 265 reduces an electric field across the channel 275 that can cause hot electron effects which degrade transistor performance.

FIG. 4 shows a transistor 300, where a spacer 270 is formed on each sidewall of the gate stack 250. Each spacer 270 comprises an insulating material such as an oxide and/or nitride based material. In some embodiments, the spacers 270 comprise a bistertiary-butylaminosilane (BTBAS) silicon nitride layer. The spacers 270 are formed by depositing one or more layers of such material(s) over the substrate 200 in a conformal manner, followed by an anisotropic etch thereof, thereby removing spacer material from the top of the gate stack 250 and the substrate 200, while leaving the spacers 270 on each of the sidewalls of the gate stack 250. Thereafter, an ion implantation 280 is performed. Depending on the type of transistor being formed (NMOS or PMOS), the ion implantation 280 implants either N-type or P-type dopants (e.g., boron for PMOS transistors, and phosphorous and/or arsenic for NMOS transistors). In particular, the ion implantation 280 is performed into the exposed portion of the active region 252 and into the exposed portion of the active region 262 in order to define a source region 285 and a drain region 290. The ion implantation 280 is a self-aligned ion implantation process in that the gate stack 250 and the spacers 270 are used as a mask to define each of the source and drain regions 285, 290. Thus, the gate stack 250 and spacers 270 are simultaneously subjected to the ion implantation 280, and the ion implantation 280 also dopes the polysilicon layer 230A. However, the gate stack 250 and spacers 270 mask a portion of the substrate 200 from the ion implantation 280, such that the source and drain regions 285, 290 are formed within the substrate 200 immediately adjacent to the spacers 270. Moreover, the spacers 270 mask an inside portion of the initial lightly doped source and drain regions 260, 265 from the ion implantation 280.

In some embodiments, the spacers 270 serve to protect (i.e., block the ion implantation 280) the sidewalls of the gate stack 250. In other embodiments, a thin conformal oxide or nitride layer is deposited over the gate stack 250 prior to the ion implantation 280 and is used to block the ion implantation 280 from the polysilicon layer 230A. In this manner, the doping of the source and drain regions 285, 290 can remain separate and independent of the doping of the polysilicon layer 230A.

The dose (Q) of the ion implantation 280 used for the source and drain regions 285, 290 is high as compared to the dose of the ion implantation 255 (FIG. 3) that is used for the lightly doped source and drain regions 260, 265. Highly doped source and drain regions 285, 290 are desirable, for example, to maintain a low contact resistance to the source and drain regions 285, 290, where the contacts are made during subsequent transistor processing. However, in order for the lightly doped source and drain regions 260, 265 to properly perform their function of reducing the electric field across the channel 275 (FIG. 1) (and thus reduce hot electron effects) it is desirable that dopants from the highly doped source and drain regions 285, 290 do not substantially diffuse from the source and drain regions 285, 290 into the lightly doped source and drain regions 260, 265. Thus, in some embodiments, the ion implantation 280 comprises a nitrogen co-implant, where the nitrogen is used to reduce the diffusivity of the dopant species (e.g., boron, phosphorous, or arsenic) by, for example, reducing an amount of net interstitial locations within a semiconductor lattice (e.g., within the substrate 200) that are available for diffusion of the dopant species. For the nitrogen co-implant, the nitrogen implant energy (i.e., projected range (Rp) of the implant) and dose are set according to the projected range and dose of the dopant species (e.g., boron, phosphorous, or arsenic). Consider for example the case of using boron as the dopant species (e.g., for a PMOS transistor) of the ion implantation 280 to define the source and drain regions 285, 290. In some embodiments, the projected range of the nitrogen co-implant is between about 0.33 and about 1.33 of the projected range of the boron implant. Thus, in some embodiments a peak concentration of the dopant species (e.g., boron) is located at a depth X₂ from the surface 271 of the substrate 200, and a peak concentration of the nitrogen is located between a depth y₂′ (corresponding to about 0.33 of the depth x₂) and a depth y₂″ (corresponding to about 1.33 of the depth x₂) from the surface 271. Each of x₂, y₂′, and y₂″, as illustrated in FIG. 4 and herein described, are intended to indicate a depth from the surface 271 and are not intended to indicate any lateral positioning of either the dopant species or the nitrogen. Also, in some embodiments, the dose of the nitrogen co-implant is between about 0.7 and about 1.3 of the boron dose. In other embodiments, the nitrogen co-implant is used together with other dopant species such as phosphorous, arsenic, or a combination of different dopants. Thus, the nitrogen co-implant enables the source and drain regions 285, 290 maintain their high doping concentration as compared to the lightly doped source and drain regions 260, 265 and thus maintain a low electric field across the channel 275 (FIG. 3) and low contact resistance to the source and drain regions 285, 290. In some embodiments, a thermal process, such as a rapid thermal anneal, is performed to activate the dopants within the source and drain regions 285, 290, which may cause a slight lateral diffusion of the source and drain regions 285, 290 under the spacers 270.

Still referring to FIG. 4, while the dose of the ion implantation 280 used for the source and drain regions 285, 290 is high as compared to the dose of the ion implantation 255 (FIG. 3) that is used for the lightly doped source and drain regions 260, 265, scaling down into the nanometer-scale regime means that it is possible that the transistor 300 is still subject to poly-depletion effects. By further increasing the dose of the dopant species used for the ion implantation 280, the doping of the polysilicon layer 230A can be increased such that the poly-depletion effect is removed or at least lessened. This results in an increased equivalent capacitance between the polysilicon layer 230A and the well 210, which decreases the effective thickness of the gate dielectric 225A (i.e., Tox Inversion), and results in increased transistor 300 drive current. Further, the co-implanted nitrogen in the source and drain regions 285, 290 assures that the diffusivity of the dopant species within the source and drain regions 285, 290 is reduced enough such that the dopant species within the source and drain regions 285, 290 will not substantially diffuse into the lightly doped source and drain regions 260, 265. Thus, a low electrical field across the channel 275 (FIG. 3) and low contact resistance to the source and drain regions 285, 290 are both maintained. In some embodiments, the physical dimensions of the transistor 300 (e.g., dimensions of the spacers 270) are scaled down from one technology generation to the next without substantially changing the dose of the dopant species used for the ion implantation 280. That is, the dose of the dopant species for a given technology generation is substantially the same as a dose used for a previous technology generation. Without the nitrogen co-implant, the dopant species within the source and drain regions 285, 290, for example, can more easily diffuse into the lightly doped source and drain regions 260, 265. However, the nitrogen introduced into the source and drain regions 285, 290 during the co-implant of the ion implantation 280 reduces the diffusivity of the dopant species such that the dopant species within the source and drain regions 285, 290 will not substantially diffuse into the lightly doped source and drain regions 260, 265. Thus, the physical dimensions of the transistor 300 (e.g., dimensions of the spacers 270) can be scaled down from one technology generation to the next without substantially changing the dose of the dopant species used for the ion implantation 280. After processing as shown in FIG. 4, other CMOS processing may follow (e.g., interlayer dielectric and metallization layers can be formed).

The above discussion is meant to be illustrative of the principles and various embodiments of the present invention. Numerous variations and modifications will become apparent to those skilled in the art once the above disclosure is fully appreciated. For example, a nitrogen co-implant may be used in cases where the polysilicon layer 230A is doped independently from the source and drain regions 285, 290. Also, unless otherwise indicated, any one or more of the layers set forth herein can be formed in any number of suitable ways (e.g., with spin-on techniques, sputtering techniques (e.g., magnetron and/or ion beam sputtering), thermal growth techniques, deposition techniques such as chemical vapor deposition (CVD), physical vapor deposition (PVD) and/or plasma enhanced chemical vapor deposition (PECVD), or atomic layer deposition (ALD)). Further, unless otherwise indicated, any one or more of the layers can be patterned in any suitable manner (e.g., via lithographic and/or etching techniques). It is intended that the following claims be interpreted to embrace all such variations and modifications.

What is claimed is:

1. A method comprising:
forming a gate stack over a substrate;
implanting a dopant species into an active region adjacent to the gate stack; and
implanting nitrogen into the active region to reduce a diffusivity of the dopant species.

2. The method according to claim 1 wherein forming the gate stack further comprises:
forming a dielectric layer over the substrate; and
forming a polysilicon layer over the dielectric layer.

3. The method according to claim 1 further comprising forming a spacer along a sidewall of the gate stack before implanting the nitrogen.

4. The method according to claim 1 further comprising forming a spacer along a sidewall of the gate stack after implanting the nitrogen.

5. The method according to claim 2 wherein forming the gate stack further comprises forming an antireflective layer over the polysilicon layer.

6. The method according to claim 1 wherein implanting the dopant species further comprises implanting the dopant species comprising one or more selected from the group consisting of: boron; phosphorous; and arsenic.

7. The method according to claim 1 wherein implanting the nitrogen further comprises setting a nitrogen implant energy according to a dopant species implant energy.

8. The method according to claim 1 wherein implanting the nitrogen further comprises setting a nitrogen implant dose according to a dopant species implant dose.

9. The method according to claim 7 wherein setting the nitrogen implant energy further comprises setting the nitrogen implant energy such that the nitrogen has a projected implant range of between about 0.33 and about 1.33 of a dopant species implant range.

10. The method according to claim 9 wherein implanting the dopant species further comprises implanting the dopant species comprising one or more selected from the group consisting of: boron; phosphorous; and arsenic.

11. The method according to claim 8 wherein setting the nitrogen implant dose further comprises setting the nitrogen implant dose to between about 0.7 and about 1.3 of the dopant species implant dose.

12. The method according to claim 11 wherein implanting the dopant species further comprises implanting the dopant species comprising one or more selected from the group consisting of: boron; phosphorous; and arsenic.

13. The method according to claim 1 wherein implanting the dopant species into the active region is simultaneous with implanting the nitrogen into the active region.

14. The method according to claim 2 wherein implanting the dopant species further comprises implanting the dopant species such that the polysilicon layer is substantially fully conductive.

15. The method according to claim 14 further comprising doping a portion of the substrate such that a channel of a transistor is substantially free of hot electrons during operation of the transistor.

16. The method according to claim 14 further comprising doping a portion of the substrate such that there is a low contact resistance to a source region and a drain region of a transistor.

17. The method according to claim 1 further comprising:
implanting the dopant species such that a peak concentration of the dopant species is located at a depth ‘x’ from a surface of the substrate; and
implanting the nitrogen such that a peak concentration of the nitrogen is located at a depth ‘y’ from the surface of the substrate;
wherein the depth ‘y’ is greater than the depth ‘x’.

18. The method according to claim 1 wherein implanting the nitrogen further comprises implanting the nitrogen into a source region and a drain region.

19. The method according to claim 1 wherein implanting the nitrogen further comprises implanting the nitrogen into a lightly doped source region and a lightly doped drain region.

20. A semiconductor device comprising:
a substrate having a surface;
an active region within the substrate comprising a dopant species implanted such that a peak concentration of the dopant species is located at a depth ‘x’ from the surface; and
a nitrogen region comprising nitrogen implanted such that a peak concentration of the nitrogen is located at a depth ‘y’ from the surface;
wherein the depth ‘y’ is greater than the depth ‘x’.

21. A method comprising:
forming a gate stack over a substrate;
implanting boron into an active region adjacent to the gate stack; and
implanting nitrogen into the active region to reduce a diffusivity of the boron.

22. The method according to claim 21 wherein implanting the nitrogen further comprises setting a nitrogen implant energy according to a boron implant energy.

23. The method according to claim 21 wherein implanting the nitrogen further comprises setting a nitrogen implant dose according to a boron implant dose.

24. The method according to claim 22 wherein setting the nitrogen implant energy further comprises setting the nitrogen implant energy such that the nitrogen has a projected implant range of between about 0.33 and about 1.33 of a boron implant range.

25. The method according to claim 23 wherein setting the nitrogen implant dose further comprises setting the nitrogen implant dose to between about 0.7 and about 1.3 of the boron implant dose.

26. The method according to claim 21 wherein implanting the boron into the active region is simultaneous with implanting the nitrogen into the active region.

27. The method according to claim 21 further comprising:
implanting the boron such that a peak concentration of the boron is located at a depth ‘x’ from a surface of the substrate; and
implanting the nitrogen such that a peak concentration of the nitrogen is located at a depth ‘y’ from the surface of the substrate;
wherein the depth ‘y’ is greater than the depth ‘x’.

28. The method according to claim 21 wherein implanting the nitrogen further comprises implanting the nitrogen into a source region and a drain region.

29. The method according to claim 21 wherein implanting the nitrogen further comprises implanting the nitrogen into a lightly doped source region and a lightly doped drain region.
